(19) United States
(12) Patent Application Publication
(10) Pub. No.: US 2012/0139570 A1
(43) Pub. Date: Jun. 7, 2012

(54) SEMICONDUCTOR DEVICE AND METHOD FOR TESTING SAME

(75) Inventors: Mitsuru SUGAWARA, Kanagawa-ken (JP); Kazunobu KATOU, Chiba-ken (JP); Toshiki SESHITA, Kanagawa-ken (JP)

(73) Assignee: KABUSHIKI KAISHA TOSHIBA, Tokyo (JP)

(21) Appl. No.: 13/227,629

(22) Filed: Sep. 8, 2011

(30) Foreign Application Priority Data
Dec. 3, 2010 (JP) 2010-270807

(51) Int. Cl. G01R 31/3187; H03K 17/687

(52) U.S. Cl. 324/750.3; 327/427

(57) ABSTRACT

According to an embodiment, a semiconductor device includes a switch circuit selecting a signal pathway between a common terminal and one of a plurality of terminals using a plurality of FETs provided in series between the common terminal and each of the terminals. The semiconductor device also includes a test switch including a plurality of FETs connected to the common terminal, an oscillation circuit connected to the common terminal via the test switch, and a detection circuit receiving an output of the oscillation circuit.

### CROSS-REFERENCE TO RELATED APPLICATIONS

This application is based upon and claims the benefit of priority from Japanese Patent Application No. 2010-270807, filed on Dec. 3, 2010; the entire contents of which are incorporated herein by reference.

### FIELD

Embodiments are generally related to a semiconductor device and a method for testing the same.

### BACKGROUND

Demand for radio-frequency switch circuits is expanding in various applications. For example, in the mobile communications systems such as cellular phones and like, multiband systems are coming into wide use, which conform to the third generation standard (3G), such as the UMTS (Universal Mobile Telecommunications System), in addition to the GSM (Global System for Mobile Communications). Hence, a mobile communication terminal includes a plurality of transmitting and receiving circuits and a radio-frequency switch circuit, such as SP6T (Single-Pole-6-Throw), which switches signal pathways between a plurality of input and output terminals. It is also required for the mobile communication terminal to downsize a semiconductor device including such a radio-frequency switch circuit and to reduce the power consumption therein. Then, the semiconductor device has been developed, in which metal oxide semiconductor field effect transistors (MOSFETs) are integrated into the radio-frequency switch circuit.

On the other hand, semiconductor devices used for mobile communication terminals are required to be low cost and high quality. For this demand, it is desirable to evaluate the radio-frequency characteristics in a test process, where the semiconductor device is determined to be good or not. However, it is necessary for evaluating the radio-frequency characteristics of the semiconductor device to introduce an expensive measurement equipment and spend a lot of time, since all the MOSFETs need to be examined in the radio-frequency switch circuit. Therefore, the semiconductor device and a method for manufacturing the same are required, where the radio-frequency characteristics are evaluated using convenient way.

### BRIEF DESCRIPTION OF THE DRAWINGS

FIG. 1 is a circuit diagram illustrating a configuration of a semiconductor device according to a first embodiment;

FIG. 2 is an equivalent circuit diagram illustrating the configuration of the semiconductor device according to the first embodiment;

FIGS. 3A and 3B are simplified equivalent circuit diagrams illustrating operation models of the semiconductor device according to the first embodiment;

FIGS. 4A and 4B are schematic diagrams illustrating changes in output voltages in the cases where one MOSFET included in the circuit is out of a normal state;

FIG. 5 is a circuit diagram illustrating an oscillation circuit according to the first embodiment;

FIG. 6 is a circuit diagram illustrating a detection circuit according to the first embodiment;

FIG. 7A is a schematic cross-sectional view illustrating a MOSFET and FIG. 7B is a schematic cross-sectional view illustrating a p-n junction diode;

FIG. 8 is a circuit diagram illustrating a configuration of a semiconductor device according to a second embodiment;

FIG. 9 is a circuit diagram illustrating a configuration of a semiconductor device according to a third embodiment;

FIG. 10 is a circuit diagram illustrating a configuration of a semiconductor device according to a fourth embodiment.

### DETAILED DESCRIPTION

In general, according to an embodiment, a semiconductor device includes a switch circuit selecting a signal pathway between a common terminal and one of a plurality of terminals using a plurality of FETs provided in series between the common terminal and each of the terminals. The semiconductor device also includes a test switch including a plurality of FETs connected to the common terminal, an oscillation circuit connected to the common terminal via the test switch, and a detection circuit receiving an output of the oscillation circuit.

Hereinbelow, embodiments of the invention are described with reference to the drawings. In the following embodiments, identical components in, the drawings are marked with the same reference numerals, and a detailed description thereof is omitted as appropriate and different components are described.

### First Embodiment

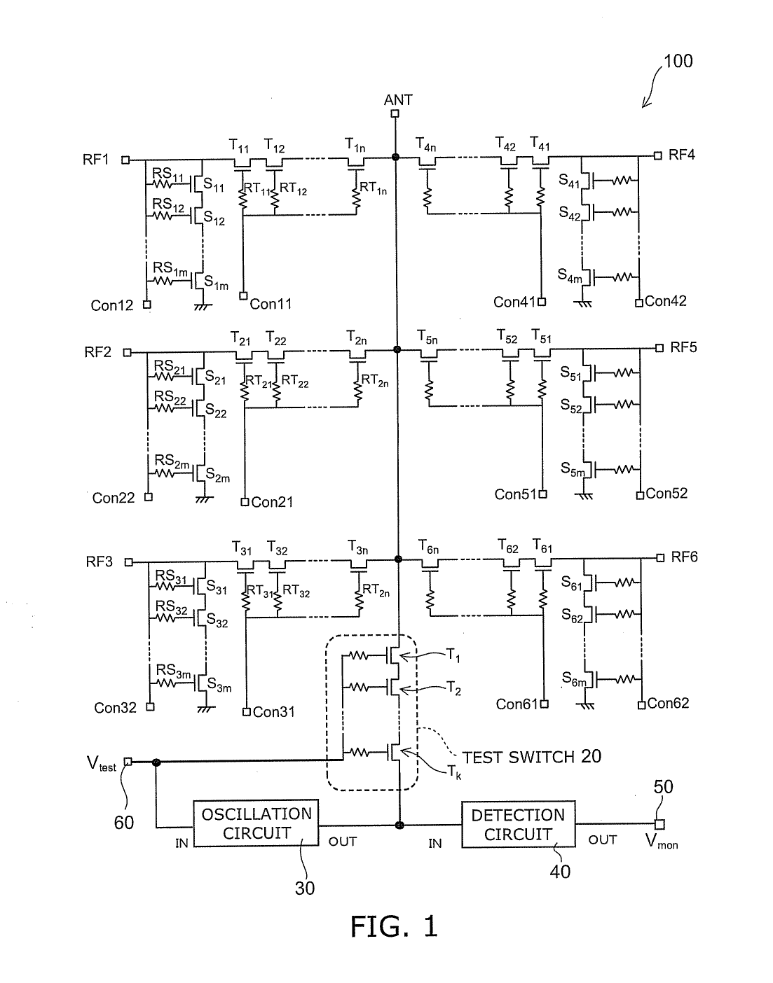

FIG. 1 is a circuit diagram illustrating the configuration of a semiconductor device 100 according to a first embodiment. The semiconductor device 100 is, for example, a radio-frequency semiconductor switch device, and includes an SP6T switch circuit that switches the signal path between an antenna terminal (ANT) 10 and a plurality of radio-frequency (RF) terminals 1 to 6, where the ANT terminal 10 is a common radio-frequency terminal.

A plurality of FETs is provided in series between the ANT terminal 10 and each of the RF terminals 1 to 6. For example, n MOSFETs (T₁₁ to T₁ₙ) are provided in series between the antenna terminal 10 and the RF terminal 1. The gates of the MOSFETs (T₁₁ to T₁ₙ) are connected to a control terminal Con11 via resistances RT₁₁ to RT₁ₙ, respectively. In addition, m MOSFETs (S₁₁ to S₁ₘ) are provided in series between the RF terminal 1 and a ground terminal (GND). The gates of the MOSFETs (S₁₁ to S₁ₘ) are connected to a control terminal Con12 via resistances RS₁₁ to RS₁ₘ, respectively.

Similarly, n MOSFETs are provided between the ANT terminal 10 and each of the RF terminals 2 to 6, and m MOSFETs are provided between each of the RF terminals 2 to 6 and the ground terminal.

For example, in the case where the signal path between the RF terminal 1 and the ANT terminal 10 is connected, a control signal S_{H} (e.g. High-level) is inputted to the control terminal Con11, and all the MOSFETs (hereinafter, “through FETs”) T₁₁ to T₁ₙ provided between the RF terminal 1 and the ANT terminal 10 are set in the ON state. A control signal S_{L} (e.g. Low-level) is inputted to the control terminal Con12, or the control terminal Con12 is kept at the zero level, and the MOSFETs (hereinafter, “shunt FETs”) S₁₁ to S₁ₘ are set in the OFF state.

On the other hand, the through FETs provided between the ANT terminal 10 and the RF terminals 2 to 6 are set in the OFF state by inputting the control signal S_{L} to the control terminals Con21 to Con61. The shunt FETs provided between the RF terminals 2 to 6 and the ground terminal are set in the ON state by inputting the control signal S_{H} to the control terminals Con22 to Con62.

Thereby, the signal path between the ANT terminal 10 and the RF terminal 1 is connected, and the signal paths between the ANT terminal 10 and the RF terminals 2 to 6 are cut off. By connecting the RF terminals 2 to 6 and the ground terminal while setting the shunt FETs in the ON state, the leakage of a radio-frequency signal from the ANT terminal 10 to the RF terminals 2 to 6 can be blocked.

As mentioned above, in the SP6T switch circuit, a control signal is inputted to the control terminals Con11 to Con61 connected to the gates of the through FETs and the control terminals Con12 to Con62 connected to the gates of the shunt FETs. A current is passed between one of the RF terminals 1 to 6 and the ANT terminal 10. The pathways between the other RF terminals and the ANT terminal 10 are cut off. Thereby, the signal pathway is switched.

For example, in a switch used for a front end of a cellular phone, a radio-frequency signal of several watts passes through the selected pathway. Accordingly, the maximum amplitude of the radio-frequency signal applied between the ANT terminal 10 and each RF terminal becomes a few 10 V during the OFF state. Since the breakdown voltage of a miniaturized MOSFET is not enough to withstand such a voltage, a plurality of MOSFETs are connected in series in a multistage manner as mentioned above. The resistances (e.g. RT₁₁ to RT₁ₙ) between the gates of the MOSFETs and the control terminal are provided in order to prevent the leakage of a radio-frequency signal.

As shown in FIG. 1, the semiconductor device 100 according to the embodiment further includes a test switch 20 connected to the ANT terminal 10 and an oscillation circuit 30 connected to the ANT terminal 10 via the test switch 20. The semiconductor device 100 further includes a detection circuit 40 receiving the output of the oscillation circuit 30 and an output terminal 50 of the detection circuit 40.

The test switch 20 includes a plurality of MOSFETs (T₁ to Tₖ) connected in series. The gates of the MOSFETs (T₁ to Tₖ) are connected to a test terminal 60, and the ON or OFF states can be controlled according to a control signal input to the test terminal 60 from the outside. The test terminal 60 is also connected to the input side of the oscillation circuit 30, and the control signal is input to the oscillation circuit 30 for outputting a radio-frequency signal.

For example, the test switch 20 is set in the ON state, and at the same time a radio-frequency signal is output from the oscillation circuit 30. Thereby, the radio-frequency signal is transmitted to the ANT terminal 10. The output of the oscillation circuit 30 is also input to the detection circuit 40, and can be monitored at the output terminal 50 as a direct-current (DC) output Vₘₒₙ.

For example, control signals are input to the control terminals Con11 to Con61 and Con12 to Con62 in order to switch the signal pathway, and the radio-frequency signal from the oscillation circuit 30 passes successively through the selected pathway between the ANT terminal 10 and the RF terminals 1 to 6. During this process, the RF terminals 1 to 6 are in the open state and the output Vₘₒₙ is monitored at the output terminal 50, thereby an impedance change between the ANT terminal 10 and the GND can be detected as a change in Vₘₒₙ.

If all the MOSFETs included in the through FETs and the shunt FETs provided between the ANT terminal 10 and the RF terminals 1 to 6 have the same specification, the impedance change between the ANT terminal 10 and the GND is not detected in Vₘₒₙ, while the signal pathways are switched as mentioned above. On the other hand, if one of the MOSFETs included in the SP6T switch circuit is out of the normal state, a impedance change is found in Vₘₒₙ when the signal pathway including the one MOSFET is selected.

If all the MOSFETs are normal, the impedance between the ANT terminal 10 and each of the RF terminals 1 to 6 is equal. “Impedance being equal” is not limited to being strictly equal but includes the case where there is a small difference due to a variation in manufacturing processes or the circuit layout and the like.

As mentioned above, in the semiconductor device 100 according to the embodiment, a control signal is input to the test terminal 60 to turn the test switch 20 to the ON state; the oscillation circuit 30 is operated at the same time; and the signal paths between the ANT terminal 10 and the RF terminals 1 to 6 are switched. Thereby, it can be determined whether the MOSFETs connected to the RF terminals are normal or not. Furthermore, the output of the detection circuit 40 is detected as a DC voltage Vₘₒₙ, thereby the radio-frequency characteristics of the SP6T switch circuit is easily evaluated whether it is good or not, without using expensive radio-frequency measurement equipment.

The oscillation circuit 30 and the detection circuit 40 are used only for evaluating the radio-frequency characteristics, and do not contribute to the normal operation of the SP6T switch circuit. Therefore, the test switch 20 is kept in the OFF state after the evaluation of the radio-frequency characteristics. The breakdown voltage of the test switch 20 is preferably set higher than the breakdown voltage between the ANT terminal 10 and the RF terminals 1 to 6. That is, the number k of the series connection stages of the plurality of MOSFETs (T₁ to Tₖ) included in the test switch 20 is preferably set not less than the number n of the series connection stages of the MOSFETs provided between the antenna terminal 10 and each of the RF terminals 1 to 6.

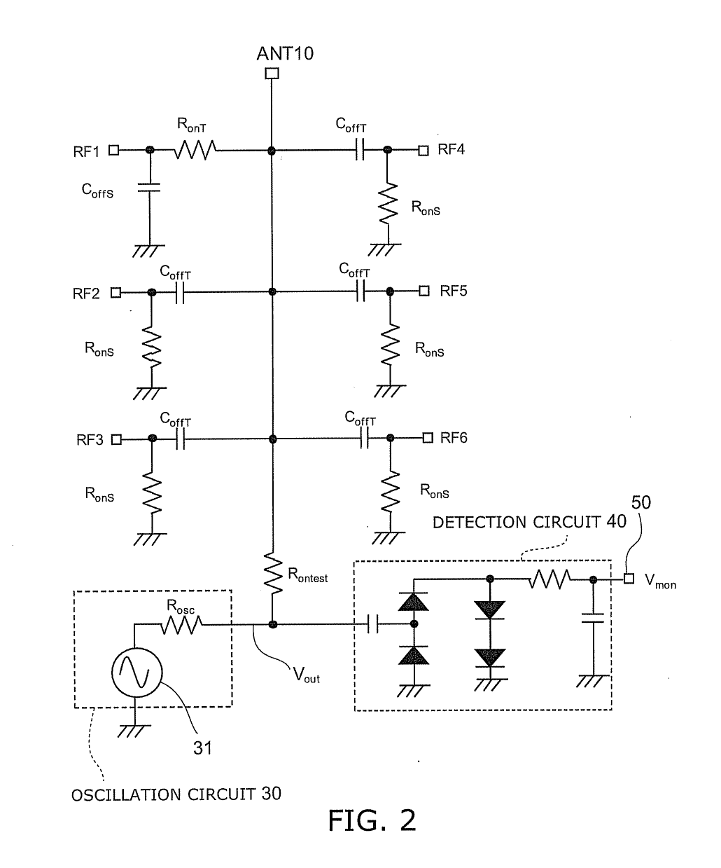

Next, the change in the output Vₘₒₙ monitored at the output terminal 50 of the detection circuit 40 is described with reference to FIG. 2 to FIG. 4.

FIG. 2 is an equivalent circuit of the semiconductor device 100 according to the first embodiment. The signal pathway between the ANT terminal 10 and the RF terminal 1 is in the conduction state, and the ON resistance (R_{onT}) of the through FETs that are the n-staged MOSFETs (T₁₁ to T₁ₙ) connected in series is shown between the ANT terminal 10 and the RF terminal 1. The shunt FETs that are the m-staged MOSFETs (S₁₁ to S₁ₘ) provided between the RF terminal 1 and the ground terminal are in the OFF state, and the capacitance (C_{offS}) is shown therebetween.

On the other hand, the pathways between the ANT terminal 10 and the RF terminals 2 to 6 are cut off, and the capacitance (C_{offT}) of the through FETs is shown between the ANT terminal and each of the RF terminals 2 to 6. The shunt FETs provided between each of the RF terminals 2 to 6 and the ground terminal are in the ON state, and the ON resistance (R_{onS}) is shown therebetween.

As described above, in the case where the radio-frequency characteristics of the SP6T switch circuit are evaluated, since the test switch 20 is set in the ON state, the ON resistance (Rₒₙₜₑₛₜ) of the test switch 20 is shown between the ANT terminal 10 and the output side of the oscillation circuit 30. The oscillation circuit 30 during operation is expressed by a radio-frequency oscillation source 31 and an inner resistance (R_{osc}). Details of the detection circuit 40 are described later.

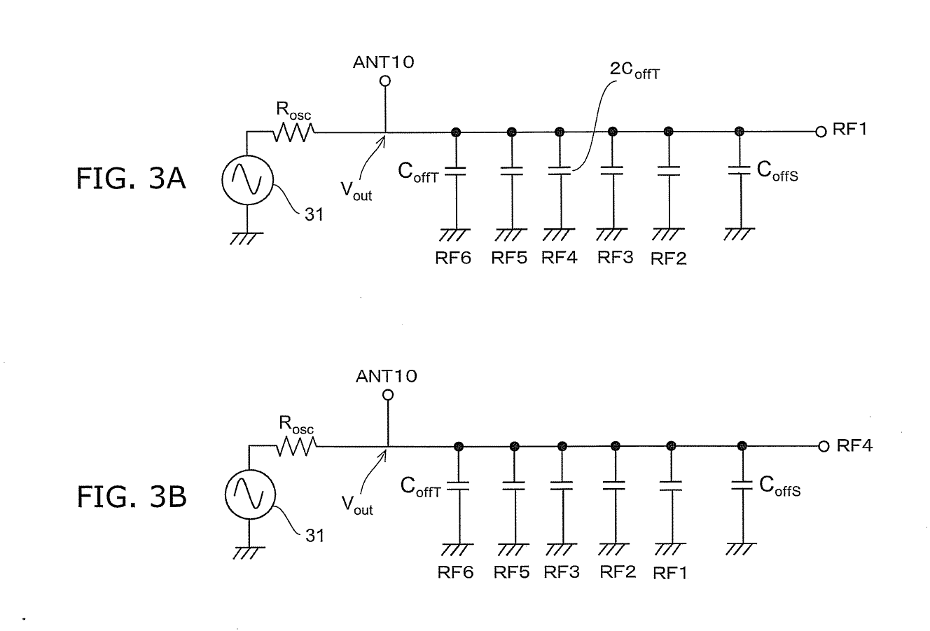

FIGS. 3A and 3B are modified equivalent circuits of the semiconductor device 100, in which the equivalent circuit of FIG. 2 is further simplified, assuming that

R_{onT}, R_{onS}, and Rₒₙₜₑₛₜ<<R_{osc},

R_{onT}, R_{onS}, and Rₒₙₜₑₛₜ are expressed as 0 (zero) Ω for the sake of convenience. As a result, in the equivalent circuits shown in FIGS. 3A and 3B, an RC circuit is connected to the output of the radio-frequency oscillation source 31.

FIG. 3A shows the state where the signal pathway between the ANT terminal 10 and the RF terminal 1 is in the conduction sate and the other pathways between the ANT terminal 10 and RF terminals 2 to 6 are cut off. Therefore, the OFF capacitance C_{offT} of the through FETs is illustrated between the ANT terminal 10 and each of the RF terminals 2 to 6 and the OFF capacitance C_{offS} of the shunt FETs is illustrated between the RF terminal 1 and the ground terminal.

For example, one MOSFET included in the through FETs connected to the RF terminal 4 is out of the normal state and the OFF capacitance becomes two times larger than those in the other terminals. In this case, if the signal pathway between the ANT terminal 10 and an RF terminal other than the RF terminal 4 is in the conduction state, the equivalent circuit includes the OFF capacitance of 2C_{offT} between the RF terminal 4 and the ANT terminal 10, as shown in FIG. 3A.

On the other hand, if the signal pathway between the RF terminal 4 and the ANT terminal 10 is in the conduction state, the OFF capacitance 2C_{offT} disappears and all become the same OFF capacitance C_{offT} as shown in FIG. 3B. Thereby, the amplitude of the output Vₒᵤₜ of the oscillation circuit 30 changes as switching the pathways, due to the impedance difference between the equivalent circuit of FIG. 3A and the equivalent circuit of FIG. 3B.

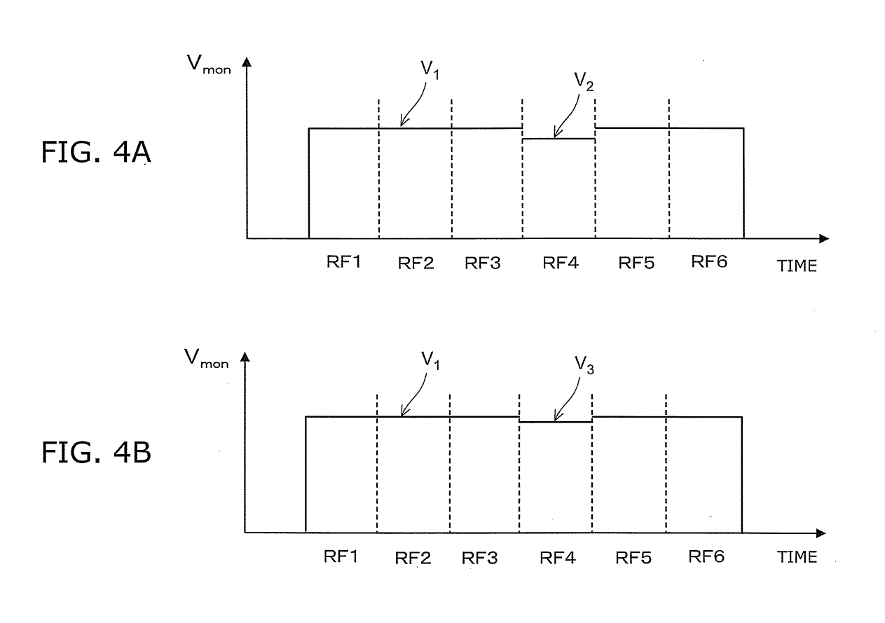

FIGS. 4A and 4B are graphs schematically illustrating the output Vₘₒₙ of the detection circuit 40. The horizontal axis represents time, and the vertical axis represents the value of Vₘₒₙ. The radio-frequency output Vₒᵤₜ is rectified in the detection circuit 40, and the output Vₘₒₙ has become a DC voltage as shown in FIGS. 4A and 4B.

FIG. 4A shows a change in the output Vₘₒₙ in the case where one MOSFET included in the through FETs provided between the RF terminal 4 and the ANT terminal 10 is out of the normal state. As shown in the horizontal axis, the radio-frequency terminal connected to the ANT terminal 10 is switched successively from the RF terminal 1 to 6. The value of Vₘₒₙ shows a change of decreasing from V₁ to V₂ when the pathway is switched from the RF terminal 3 to the RF terminal 4, and returning to V₁ when the pathway is switched from the RF terminal 4 to the RF terminal 5.

To estimate the values of V₁ and V₂, the output Vₘₒₙ of the detection circuit 40 was simulated, giving the circuit constants shown in Table 1 to the equivalent circuit of FIG. 2, where the OFF capacitance of the through FET connected to the RF terminal 4 was set to 2C_{offT}.

TABLE 1

| | | |
|---|---|---|
| Oscillation frequency of oscillation circuit | 1 | GHz |
| ON resistance of through FET | 3.7 | ohm |
| ON resistance of shunt FET | 12 | ohm |
| OFF capacitance of through FET | 0.099 | pF |
| OFF capacitance of shunt FET | 0.033 | pF |
| ON resistance of test switch | 100 | ohm |

As a result, the value of V₁ was 1.214 V, and the value of V₂ was 1.142 V. The difference between V₁ and V₂ is 72 mV, which is a detectable value. Therefore, by monitoring the output Vₘₒₙ of the detection circuit 40 according to this embodiment as mentioned above, it can be detected whether the through FETs provided between the ANT terminal 10 and each of the RF terminals 1 to 6 include the MOSFET being out of the normal state or not.

FIG. 4B shows the output Vₘₒₙ in the case where one MOSFET included in the shunt FETs provided between the RF terminals 1 to 6 and the ground terminal is out of the normal state. In regard to the shunt FET, when the pathway between one of the RF terminals 1 to 6 and the ANT terminal 10 is selected, the OFF capacitance C_{offS} appears between the one terminal and the ground terminal.

As shown in FIG. 4B, for example, the shunt FETs provided between the RF terminal 4 and the ground terminal include the MOSFET being out of the normal state, the value of Vₘₒₙ shows a change from V₁ to V₃ when the signal pathway is switched from the RF terminal 3 to the RF terminal 4, and returns from V₃ to V₁ when the signal pathway is switched from the RF terminal 4 to the RF terminal 5. Thus, by monitoring the output Vₘₒₙ of the detection circuit 40, it can also be detected whether the shunt FETs provided between each of the RF terminals 1 to 6 and the ground terminal include the MOSFET being out of the normal state or not.

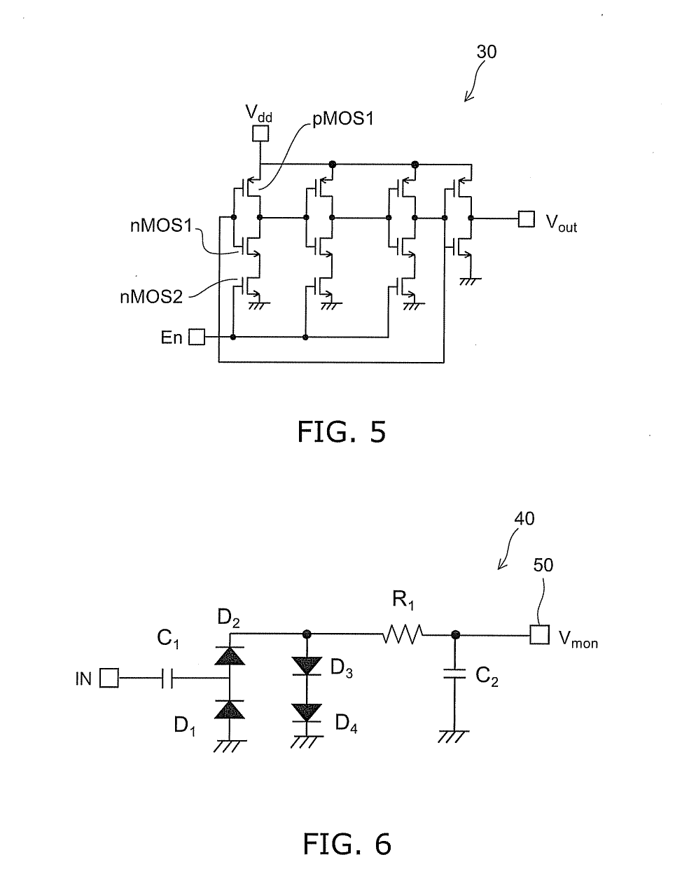

Next, the oscillation circuit 30 and the detection circuit 40 are described with reference to FIG. 5 and FIG. 6.

FIG. 5 shows the oscillation circuit 30 according to the embodiment. As shown in FIG. 5, the oscillation circuit 30 includes a ring oscillator formed of p-channel MOSFETs (pMOS1) and n-channel MOSFETs (nMOS1). The ring oscillator includes three-staged CMOS inverters arranged in parallel. In each CMOS inverter, a power source (V_{dd}) is connected to the source side of the pMOS1. On the other hand, the drain side of a second n-MOSFET (nMOS2) is connected to the source side of the nMOS1. The source side of the nMOS2 is grounded, and the gate of the nMOS2 is connected to an Enable terminal (En).

For example, while the control signal S_{H} is input to the En terminal, which is the input terminal of the oscillation circuit 30, the nMOS2 turns to the ON state and the ring oscillator starts and maintains an oscillating operation. On the other hand, when the control signal S_{L} or the zero level is applied to the En terminal, the nMOS2 turns to the OFF state and the ring oscillator stops the oscillating operation. Furthermore, as shown in FIG. 5, the back gate of each MOSFET included in the oscillation circuit 30 is provided in an electrically floating state. Thereby, for example, the oscillation circuit 30 may operates with the radio-frequency oscillation of several gigahertz.

FIG. 6 is a circuit diagram illustrating the detection circuit 40 according to the embodiment. As shown in FIG. 6, the detection circuit 40 includes a first diode (D₁), a second diode (D₂), and a low-pass filter.

The anode of D₁ is grounded, and the cathode of D₁ and the anode of D₂ are connected. The low-pass filter formed of a resistance R₁ and a capacitance C₂ is provided between the cathode of D₂ and the output terminal 50. The output of the oscillation circuit 30 is connected between D₁ and D₂ via a capacitance C₁. The anode of a third diode (D₃) is connected to the connection point of the cathode of D₂ and the low-pass filter, the cathode of D₃ is connected to the anode of a fourth diode (D₄), and the cathode of D₄ is grounded.

The capacitance C₁ and the diodes D₁ and D₂ on the input side constitute a charge pump, and increase the electric potential of the cathode side of D₂. More specifically, C₁ is charged when the radio-frequency output of the oscillation circuit 30 is minus, the voltage across C₁ is added to the plus side amplitude of the radio-frequency output, and the higher voltage is output at the cathode side of D₂.

On the other hand, the diodes D₃ and D₄ constitute a clamp circuit, and a voltage larger than the sum of the built-in voltage of D₃ and the built-in voltage of D₄ is clamped. The electric potential of the cathode side of D₂, which is the output of the charge pump, changes in accordance with the amplitude of the radio-frequency signal input from the IN terminal side, and is output as the DC voltage Vₘₒₙ that is smoothed and denoised by the low-pass filter.

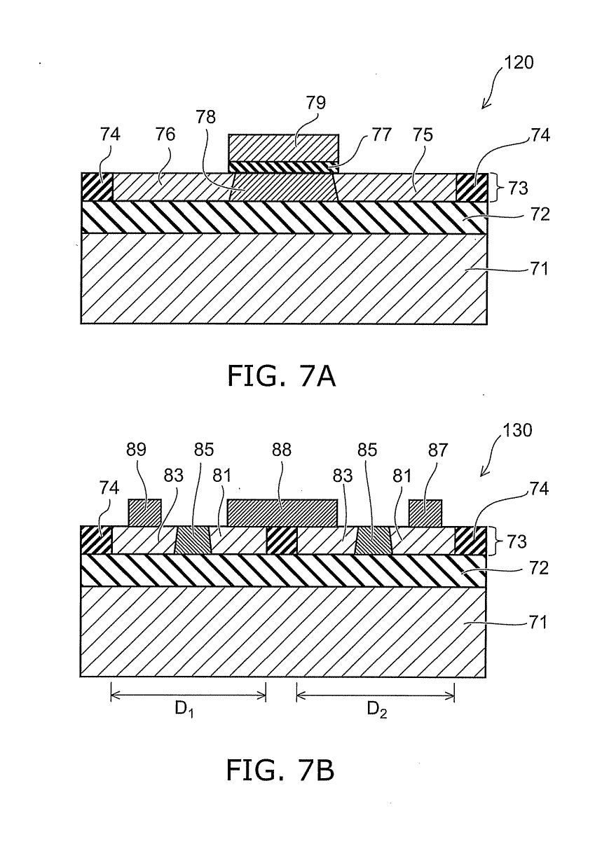

FIGS. 7A and 7B are cross-sectional views schematically illustrating the structures of a MOSFET and a p-n junction diode according to the embodiment. FIG. 7A shows a cross section of the MOSFET, and FIG. 7B shows a cross section of the p-n junction diode.

As shown in FIG. 7A, a MOSFET 120 used for the switch circuit and the oscillation circuit 30 according to this embodiment is provided in an SOI (silicon on insulator) layer 73 provided above a silicon substrate 71 via an embedded oxide film layer 72. For example, a p-type body region 78, an n-type source region 76, and an n-type drain region 75 may be formed in the SOI layer 73 using the ion implantation method. A gate electrode 79 is formed above the p-type body region 78 via a gate insulating film 77. Thereby, an n-channel MOSFET can be formed. An element isolation region 74 formed of, for example, a silicon dioxide film (SiO₂) is provided on the outside of the n-type source region 76 and the n-type drain region 75 to isolate the MOSFETs.

In a MOSFET formed directly on a silicon substrate, since the parasitic capacitance becomes large between the silicon substrate and the source region or drain region, the response speed is limited to the lower frequency range and the power loss becomes large in the radio-frequency band.

In contrast, the MOSFET provided on the substrate having an SOI structure has the advantage that the parasitic capacitance can be reduced with respect to the one directly provided on the silicon substrate and the power loss can be reduced in the radio-frequency band. Furthermore, it can be easily fabricated due to a simpler structure than the one provided directly on the silicon substrate. Thus, according to the embodiment, a semiconductor device 100 having excellent radio-frequency characteristics can be obtained by providing the radio-frequency switch circuit and the oscillation circuit 30 on the SOI substrate.

A p-n junction diode 130 illustrated in FIG. 7B is provided with two diodes D₁ and D₂ connected in series. That is, the diodes D₁ and D₂ including an n⁺ region 81, an n region 85, and a p⁺ region 83 are provided in the SOI layer 73 provided above the silicon substrate 71 via the embedded oxide film layer 72. An electrode 88 is provided to connect D₁ and D₂ in series. That is, the electrode 88 is electrically connecting the n⁺ region 81, which is the cathode side of D₁, and the p⁺ region 83, which is the anode side of D₂.

An anode electrode 89 is provided on the p⁺ region 83 of D₁, and a cathode electrode 87 is provided on the n⁺ region 81 of D₂. D₁ and D₂ are insulated from each other by the element isolation region 74.

Thus, the structure in which the diodes D₁ and D₂ are connected in series can be easily formed by using the SOI substrate. The diodes D₁ and D₂ can have an ideal two-terminal structure insulated by the embedded oxide film layer 72.

For example, in the case where the detection circuit 40 is provided directly on a silicon substrate, a simple configuration like the above cannot be applied due to a p-n junction formed between the silicon substrate and D₁ or D₂, and it is necessary to use a more complicated structure.

As described above, since the MOSFET and the diode provided on the SOI substrate have the simplified structures, the oscillation circuit 30 and the detection circuit 40 can be provided in a smaller area. Therefore, the embodiment is advantageous in the demand for reducing the chip size of the semiconductor device.

### Second Embodiment

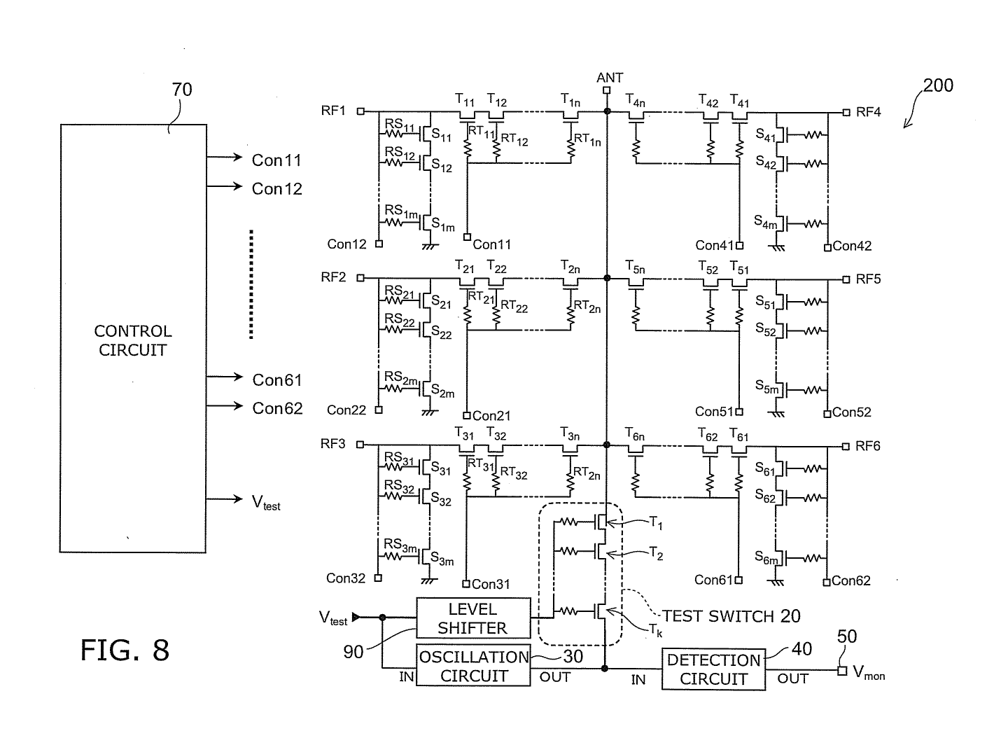

FIG. 8 is a circuit diagram showing the configuration of a semiconductor device 200 according to a second embodiment. The semiconductor device 200 is different from the semiconductor device 100, where the semiconductor device 200 includes a control circuit 70 provided on the same substrate and the control circuit 70 gives a control signal (Vₜₑₛₜ) to the oscillation circuit 30 and the test switch 20. Hence, the test terminal 60 is not provided in the semiconductor device 200.

The control circuit 70 decodes, for example, an external signal that selects the signal pathway between the ANT terminal 10 and the RF terminals 1 to 6 in the SP6T switch circuit. Furthermore, the control circuit 70 outputs a control signal to the control terminals Con11 to Con61 and Con12 to Con62 of the switch circuit, and outputs Vₜₑₛₜ.

A level shifter 90 is further provided for adjusting the level of Vₜₑₛₜ that the control circuit 70 outputs. That is, the level shifter 90 generates an electric potential capable of driving the test switch 20.

Thereby, by giving an external signal to the control circuit 70, the radio-frequency characteristics can be evaluated in the SP6T switch circuit. Furthermore, the element area may be decreased by not providing the test terminal 60.

### Third Embodiment

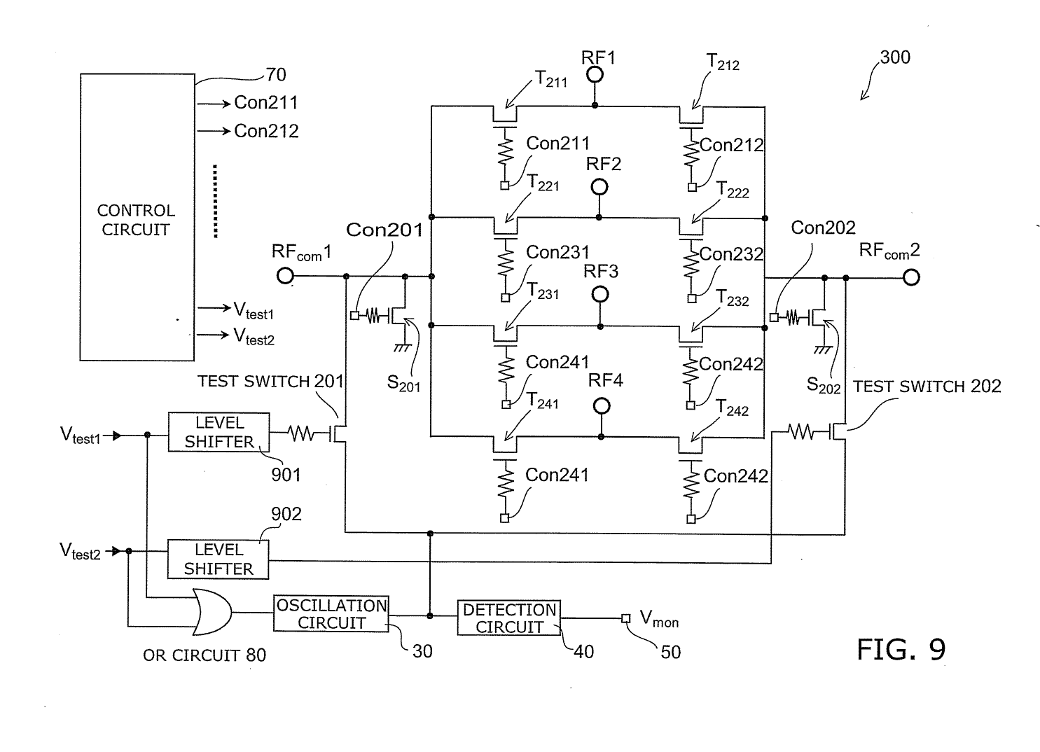

FIG. 9 is a circuit diagram illustrating the configuration of a semiconductor device 300 according to a third embodiment. The semiconductor device 300 includes the mPnT switch circuit (m and n being integers not less than two). For example, FIG. 9 shows a DP4T (Double Pole Four Throw) switch circuit. The DP4T switch circuit includes two common RF terminals (corresponding to the ANT terminal) RF_{com}1 and RF_{com}2, and switches the signal pathway connecting to each of the RF terminals 1 to 4. For example, in the case where the pathway between the RF_{com}1 and the RF terminal 1 is selected, the through FET (T₂₁₁) is set in the ON state and the shunt FET (S₂₀₁) is set in the OFF state. On the other hand, the through FET (T₂₁₂) and the through FETs connected to the RF terminals 2 to 4 are set in the OFF state and the shunt FET (S₂₀₂) on the RF_{com}2 side is set in the ON state.

Each through FET and each shunt FET include a plurality of MOSFETs connected in series (not shown). The gates of the MOSFETs are connected to the control terminals Con211 to Con242 and Con201 and Con202 via high resistances. Each control terminal is connected to the control circuit 70.

The oscillation circuit 30 of the semiconductor device 300 is connected to RF_{com}1 via a test switch 201 and connected to RF_{com}2 via a test switch 202. The output of the oscillation circuit 30 is input to the detection circuit 40, and the output terminal 50 for monitoring the output of the detection circuit 40 is provided.

The control circuit 70 outputs a control signal for selecting the signal pathway between RF_{com}1 or RF_{com}2 and the RF terminals 1 to 4. Furthermore, the control circuit 70 outputs control signals Vₜₑₛₜ₁ and Vₜₑₛₜ₂ for turning the test switches 201 and 202 to the ON state.

During the evaluation of the radio-frequency characteristics of the DP4T switch circuit, where the through FETs (T₂₁₁ to T₂₄₁) and the shunt FET (S₂₀₁) provided between RF_{com}1 and the RF terminals 1 to 4 are examined, Vₜₑₛₜ₁ is input to the test switch 201 via a level shifter 901. In the case where the through FETs (T₂₁₂ to T₂₄₂) and the shunt FET (S₂₀₂) provided between RF_{com}2 and the RF terminals 1 to 4 are examined, Vₜₑₛₜ₂ is input to the test switch 202 via a level shifter 902. When one of Vₜₑₛₜ₁ and Vₜₑₛₜ₂ is inputted, an OR circuit 80 outputs a control signal to the oscillation circuit 30 to turn the operation state.

Thereby, a radio-frequency signal is supplied from the oscillation circuit 30 to the DP4T switch circuit. By monitoring the output Vₘₒₙ of the detection circuit 40, it can be evaluated whether all of the MOSFETs included in the through FETs (T₂₁₁ to T₂₄₁ and T₂₁₂ to T₂₄₂) and the shunt FETs (S₂₀₁ and S₂₀₂) are in the normal state or not.

### Fourth Embodiment

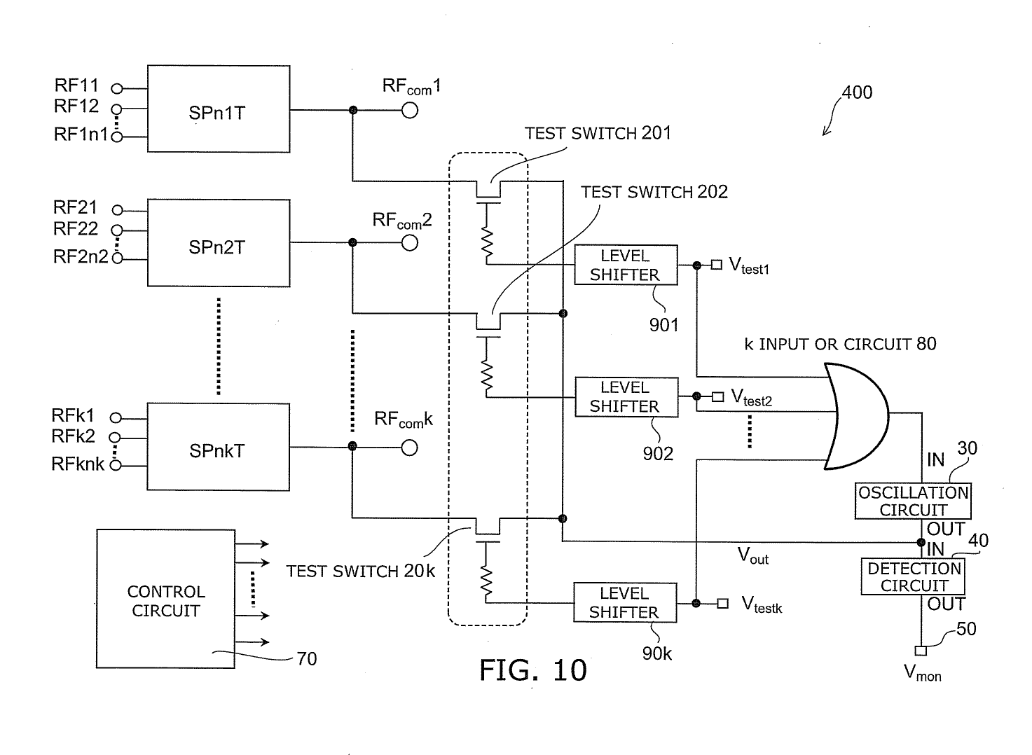

FIG. 10 is a circuit diagram showing the configuration of a semiconductor device 400 according to a fourth embodiment. The semiconductor device 400 includes a switch circuit including k SPnT switches (n and k being integers not less than two). Each SPnT switch includes n1 to nk RF terminals and a common RF terminal (RF_{com}1 to k), respectively.

As shown in FIG. 10, the oscillation circuit 30 is connected to the common RF terminals (RF_{com}1 to k) via test switches 201, 202 to 20k, respectively. The output of the oscillation circuit 30 is input to the detection circuit 40, and the output Vₘₒₙ of the detection circuit 40 can be monitored at the output terminal 50.

The control circuit 70 outputs a control signal for selecting the signal pathway between the common RF terminal in each SPnT switch and the individual RF terminals. Furthermore, the control circuit 70 evaluates the radio-frequency characteristics of each SPnT switch, and outputs control signals Vₜₑₛₜ₁ to Vₜₑₛₜₖ for evaluating whether all of the MOSFETs included in each SPnT switch are in the normal state or not.

The radio-frequency characteristics of each SPnT switch are successively evaluated, and Vₜₑₛₜ₁ to Vₜₑₛₜₖ output from the control circuit 70 are input to the gates of the test switches 201, 202 to 20k via level shifters 901, 902 to 90k, respectively.

For example, in the case where the radio-frequency characteristics of the SPn1T switch are evaluated, Vₜₑₛₜ₁ is input to the gate of the test switch 201 and the test switch 201 turns to the ON state. At the same time, Vₜₑₛₜ₁ is inputted to a k input OR circuit 80, and a control signal is input from the output side of the k input OR circuit 80 to the oscillation circuit 30 to turn the oscillation circuit 30 to the operation state. While the signal pathways between RF_{com}1, which is a common RF terminal of the SPn1 switch, and the RF terminals 11, 12 to 1n1 are switched, the output Vₘₒₙ of the detection circuit 40 is successively monitored at the output terminal 50. Thereby, it can be evaluated whether all of the MOSFETs included in the SPn1 switch are in the normal state or not. Subsequently, Vₜₑₛₜ₁ is returned to the zero level to turn the test switch 201 to the OFF state, and the evaluation of another SPnT switch is performed.

As mentioned above, even in a semiconductor device including a large-scale switch circuit like the semiconductor device 400 according to the embodiment, by providing the test switches 201 to 20k, the oscillation circuit 30, the detection circuit 40, and the output terminal 50 of the detection circuit 40, the radio-frequency characteristics of the switch circuit can be easily tested by the DC evaluation and it can be detected whether all of the MOSFETs included in the switch circuit is in the normal state or not.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device comprising:
a switch circuit selecting a signal pathway between a common terminal and one of a plurality of terminals using a plurality of FETs provided in series between the common terminal and each of the terminals,
a test switch including a plurality of FETs connected to the common terminal;
an oscillation circuit connected to the common terminal via the test switch; and
a detection circuit receiving an output of the oscillation circuit.

2. The device according to claim 1, further comprising a test terminal inputting a control signal to the oscillation circuit.

3. The device according to claim 1, further comprising a control circuit selecting a signal pathway between the common terminal and one of the terminals in the switch circuit,
the control circuit inputting a control signal to the test switch and the oscillation circuit.

4. The device according to claim 3, wherein the control circuit turns the plurality of FETs provided between the one of the terminals and the common terminal to an ON state and turns the plurality of FETs provided between each of the other terminals and the common terminal to an OFF state.

5. The device according to claim 3, wherein two of the common terminals are included in the switch circuit and two of the test switches are provided between the switch circuit and the oscillation circuit, each of the test switches being connected to either one of the two common terminals,
wherein the control circuit turns one of the test switches to an ON state to select the plurality of FETs connected to one of the common terminals.

6. The device according to claim 5, further comprising an OR circuit receiving two control signals, each of the control signals being output from the control circuit to either one of the two test switches,
wherein the oscillation circuit operates when receiving an output of the OR circuit.

7. The device according to claim 3, wherein a plurality of the switch circuits are connected to the oscillation circuit and a plurality of the test switches are provided between the switch circuits and the oscillation circuit,
wherein each of the test switches are connected to any one of a plurality of common terminals included in the switch circuits and the control circuit turns one of the test switches to an ON state to select one of the switch circuits.

8. The device according to claim 7, further comprising an OR circuit receiving a plurality of control signals, each of the control signals being output from the control circuit to any one of the test switches,
wherein the oscillation circuit operates when receiving an output of the OR circuit.

9. The device according to claim 3, further comprising a level shifter for adjusting a level of the control signal.

10. The device according to claim 1, wherein a breakdown voltage of the test switch is higher than a breakdown voltage between each of the terminals and the common terminal.

11. The device according to claim 1, wherein a number of series connection stages of the FETs included in the test switch is larger than a number of the FETs provided between the common terminal and each of the terminals.

12. The device according to claim 1, wherein
the switch circuit includes a plurality of shunt FETs connected in series between each of the terminals and a ground terminal and
the shunt FETs connected to one of the terminals are set in an ON state when the plurality of FETs provided between the one of the terminals and the common terminal are in an OFF state.

13. The device according to claim 1, wherein the switch circuit includes a plurality of shunt FETs connected in series between each of the terminals and a ground terminal and
the shunt FETs connected to one of the terminals are set in an OFF state when the plurality of FETs provided between the one of the terminals and the common terminal are in an ON state.

14. The device according to claim 1, wherein all impedances between a plurality of the terminals and the common terminal are equal in a normal state.

15. The device according to claim 1, wherein the switch circuit, the test switch, the oscillation circuit and the detection circuit are provided in an SOI (silicon on insulator) layer.

16. The device according to claim 1, wherein
the oscillation circuit includes a plurality of MOSFETs and a back gate of the MOSFET is in an electrically floating state.

17. The device according to claim 1, wherein the detection circuit outputs direct-current (DC) voltage.

18. The device according to claim 1, wherein
the detection circuit includes a first diode, a second diode, and a low-pass filter, wherein
an anode of the first diode is grounded;
a cathode of the first diode is connected to an anode of the second diode;
the low-pass filter is provided between a cathode of the second diode and the output terminal; and
an output of the oscillation circuit is connected between the first diode and the second diode via a capacitance.

19. A method for testing a semiconductor device including a switch circuit comprising:
inputting a control signal to a test switch and an oscillation circuit in order to turn the test switch to an ON state and output a radio-frequency signal from the oscillation circuit to the switch circuit, the test switch being provided between a common terminal of the switch circuit and the oscillation circuit;
sequentially selecting one of signal pathways including FETs provided between the common terminal and a plurality of terminals in the switching circuit by way of turning the FETs included in the selected signal pathway to an ON state; and
monitoring an output of a detection circuit recovering the output of the oscillation circuit in order to detect an impedance change in the switching circuit.

20. The method according to claim 19, wherein the impedance change is detected by monitoring a change in a DC output of the detection circuit.
